(19) United States
(12) Patent Application Publication
(10) Pub. No.: US 2026/0130222 A1
(43) Pub. Date: May 7, 2026

(54) REDUCED WARPAGE ELECTRONIC PACKAGE AND PACKAGING STRUCTURE

(71) Applicant: International Business Machines Corporation, Armonk, NY (US)

(72) Inventors: Katsuyuki Sakuma, Fishkill, NY (US); Qianwen Chen, Fort Collins, CO (US); Sathyanarayanan Raghavan, Ballston Lake, NY (US); John Lucas Darling, Ballston Spa, NY (US); Roy R. Yu, Poughkeepsie, NY (US)

(21) Appl. No.: 18/940,391

(22) Filed: Nov. 7, 2024

(51) Int. Cl. H01L 23/00; H01L 23/18; H01L 23/29; H01L 23/31; H01L 23/498; H01L 25/065

(52) U.S. Cl. CPC H10W 42/121; H10W 70/65; H10W 74/131; H10W 74/473; H10W 76/42; H10W 90/00; H10W 74/10; H10W 90/724

(57) ABSTRACT

An electronic package is provided which includes a continuous stiffener element (i.e., frame) located around a semiconductor die. The continuous stiffener element has a coefficient of thermal expansion (CTE) that closely matches the CTE of a carrier substrate that is located beneath the semiconductor die. The closely matched CTA between the continuous stiffener element and the carrier substrate reduced warpage in an electronic package containing the same. A molding component can be disposed between the continuous stiffener element and the semiconductor die. The electronic package having the reduced warpage can be used as a component of an electronic packaging structure.

### BACKGROUND

The present application relates to semiconductor technology, and more particularly to an electronic package, i.e., a zero (0^{th}) level package, having reduced warpage, and an electronic packaging structure that includes the reduced warpage electronic package.

Warpage is one concern in advanced packaging, such as, for example, die-to-Si carrier chiplets, where a heterogeneous mix of materials can cause uneven stress points during assembly and packaging, and under real workloads in the field. Warpage can play a critical role in determining whether an advanced package can be assembled successfully and meet long-term reliability targets. New advances, such as molding compounds with improved thermal properties, advanced modeling techniques, and creative architectures involving two molding steps have been used to enable greater control over package warpage, while also providing more flexibility to optimize a robust multi-chip (i.e., die) system.

Warpage is the inevitable result of the mismatch in coefficients of thermal expansion (CTEs) and modulus between the silicon chip, molding compound, copper wiring, and other materials. Warpage can change throughout the assembly process, and can cause cracking or delamination failures.

Even when warpage is effectively addressed during assembly and packaging, a device still may warp under heavy usage in the field. This is particularly the case in heterogeneous designs, where chips (or die) are developed using different materials or processes.

### SUMMARY

An electronic package, which can be used as a component of an electronic packaging structure, is provided that includes a continuous stiffener element (i.e., frame) located around a semiconductor die. The continuous stiffener element has a CTE that closely matches the CTE of a carrier substrate that is located beneath the semiconductor die. A molding component can be disposed between, and beneath, the continuous stiffener element and the semiconductor die.

In one embodiment of the present application, an electronic package is provided that includes a continuous stiffener element located around an entire perimeter of a semiconductor die, a molding component located between, and beneath, the continuous stiffener element and the semiconductor die, and a carrier substrate attached to the continuous stiffener element and the semiconductor die. In accordance with the present application, the continuous stiffener element is composed of a stiffener material having a CTE that closely matches a CTE of the carrier substrate. The electronic package can be in die form or in wafer form. The electronic package can be a 0^{th} level package within an electronic packaging structure.

In another embodiment of the present application, an electronic package is provided that includes a plurality of semiconductor die attached to a carrier substrate. Each semiconductor die of the plurality of semiconductor die is surrounded by a continuous stiffener element, in which the continuous stiffener element is composed of a stiffener material having a CTE that closely matches a CTE of the carrier substrate. The electronic package also includes a molding component located between, and beneath, the continuous stiffener element and each semiconductor die. The electronic package can be in die form or in wafer form. The electronic package can be a 0^{th} level package within an electronic packaging structure.

In yet another embodiment, an electronic packaging structure is provided that includes a 0^{th} level package including a continuous stiffener element located around an entire perimeter of a semiconductor die, a molding component located between, and beneath, the continuous stiffener element and the semiconductor die, and a carrier substrate attached to the continuous stiffener element and the semiconductor die, in which the continuous stiffener element is composed of a stiffener material having a CTE that closely matches a CTE of the carrier substrate. The electronic packaging structure further includes a first level stiffener element located adjacent to the 0^{th} level package, a first level molding component located between the 0^{th} level package and the first level stiffener element, and beneath the first level stiffener element, and a first laminate attached to the carrier substrate and in contact with the first level molding component.

As used throughout the present application, the term “closely matches” when referred to a CTE between a first material and a second material denotes that the CTE of the first material is typically within 10% to 20% of the CTE of the second material. In some embodiments, the CTE of the first material is within 10%, 5% or even 1 % of the CTE of the second material. In some embodiments, the CTE of the first material can equal the CTE of the second material.

### BRIEF DESCRIPTION OF THE DRAWINGS

FIG. 1A is a top down view of an electronic package (i.e., 0^{th} level package) in accordance with an embodiment of the present application.

FIG. 1B is a cross sectional view of the electronic package along X-X shown in FIG. 1A.

FIG. 1C is a three-dimensional (3D) view of an electronic package of the present application without the molding component and on a carrier substrate and after dicing.

FIG. 2 is a cross sectional view of an exemplary electronic packaging structure in accordance with an embodiment of the present application, the exemplary electronic packaging structure including a 0^{th} level package as illustrated in FIG. 1B attached to a first laminate and then to a second laminate.

FIG. 3A is a cross sectional view of an initial 0^{th} level package in die form in accordance with an embodiment of the present application.

FIG. 3B is a top down view of an initial 0^{th} level package in wafer form in accordance with an embodiment of the present application.

FIG. 4A is a cross sectional view of the initial 0^{th} level package illustrated in FIG. 3A after attaching a semiconductor die thereto.

FIG. 4B is a top down view of the initial 0^{th} level package illustrated in FIG. 3B after attaching a semiconductor die thereto.

FIG. 5A is a cross sectional view of the 0^{th} level package illustrated in FIG. 4A after forming a molding component in gaps that are located between the continuous stiffener element and semiconductor die.

FIG. 5B is a top down view of the 0^{th} level package illustrated in FIG. 4B after forming a molding component in gaps that are located between the continuous stiffener element and semiconductor die

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

Wafer molding is a critical process in 3D package technology for several reasons including (1) capsulation and protection, (2) enhanced electrical isolation, (3) package miniaturization and integration, and (4) cost efficiency. However, due to CTE mismatch between the molding component and the carrier substrate in which the semiconductor die are mounted on, the build-up thermal stresses during packaging processes result in a large warpage which can be a few millimeters, leading to package failure.

The present application solves the above warpage problem by increasing the stiffener ratio and reducing the molding component ratio on top of the carrier substrate. Notably, the present application provides an electronic package that includes a continuous stiffener element (e.g., frame) located around an entire perimeter of a semiconductor die that is mounted on a carrier substrate in which the continuous stiffener element is composed of a stiffener material having a CTE that closely matches the CTE of the carrier structure. In some embodiments, the molding component includes a filler, and the filler has a CTE that closely matches the CTE of both the stiffener and the carrier substrate. The closely matched CTEs facilitate warpage reduction in the electronic package. The electronic package having the reduced warpage can be used as a component of an electronic packaging structure.

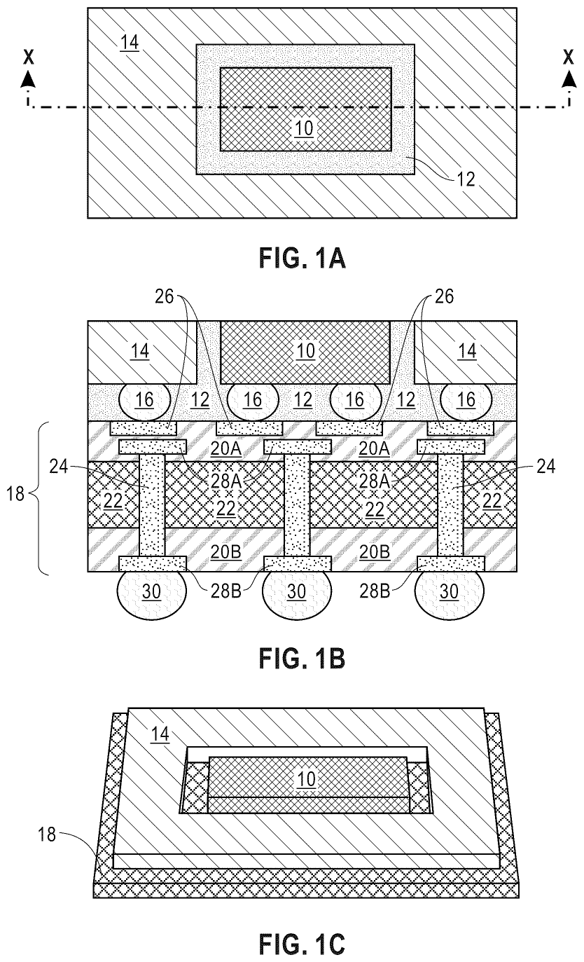

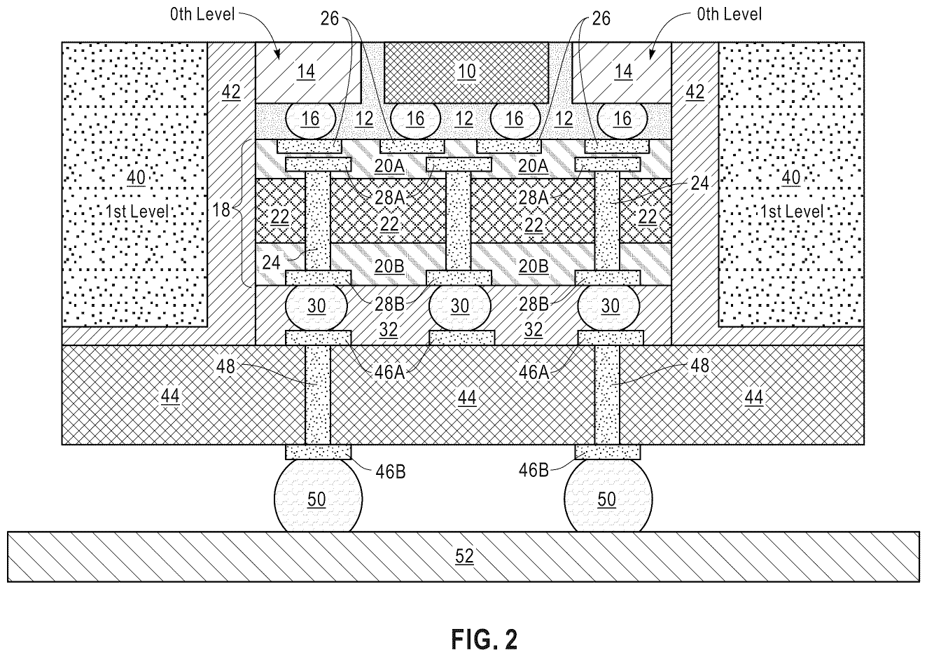

Referring first to FIGS. 1A and 1B there are illustrated various views of an electronic package in accordance with an embodiment of the present application. The electronic package illustrated in FIGS. 1A-1B can be used a zero (0^{th}) level package in an electronic packaging structure such as, for example, the electronic packaging structure illustrated in FIG. 2. Notably, FIGS. 1A and 1B illustrate an electronic package in accordance with an embodiment of the present application which includes a continuous stiffener element 14 located around an entire perimeter of a semiconductor die 10, and a molding component 12 located between the continuous stiffener element 14 and the semiconductor die 10. It is noted that continuous stiffener element 14 can also be referred to as a 0^{th} level stiffener element, and molding component 12 can also be referred to as a 0^{th} level molding component. The semiconductor die 10 and the continuous stiffener element 14 are mounted to a carrier substrate 18 as is illustrated in FIG. 1B. As shown in FIG. 1A, the molding component 12 also surrounds the perimeter of the semiconductor die 10. As is shown in FIG. 1B, the molding component 12 is located between and beneath the continuous stiffener element 14 and the semiconductor die 10. In accordance with the present application, the continuous stiffener element 14 is composed of a stiffener material having a CTE that closely matches a CTE of the carrier substrate 18. The continuous aspect of the continuous stiffener element 14 together with having the CTE of the continuous stiffener element 14 closely matching the CTE of the carrier substrate 18 reduces warpage of the resultant electronic package.

The various elements shown in the electronic package illustrated in FIGS. 1A-1B (and FIG. 1C) will now be described in greater detail. Semiconductor die 10 includes at least a front-end-of-the-line (FEOL) level that contains at least one semiconductor device disposed on a semiconductor substrate. Typically, the FEOL level includes a plurality of semiconductor devices that can form an integrated circuit. The semiconductor substrate of the FEOL level that is present in the semiconductor die 10 includes a semiconductor material. The term “semiconductor material” is used throughout the present application to denote a material having semiconducting properties. Examples of semiconductor materials that can be used in the present application include, but are not limited to, silicon (Si), a silicon germanium (SiGe) alloy, a silicon germanium carbide (SiGeC) alloy, germanium (Ge), III/V compound semiconductors or II/VI compound semiconductors. The at least one semiconductor device can be a transistor, a resistor, a capacitor, or any combination thereof. In one embodiment, the at least one semiconductor device is a transistor. A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. The gate structure includes a gate dielectric and a gate electrode. When a transistor is used as the at least one semiconductor device, the transistor can be a planar transistor, or a non-planar transistor including, but not limited to, a FinFET, a nanosheet transistor, a nanowire transistor, a fork sheet transistor, or a FET stack including at least one transistor stack above another transistor.

The semiconductor die 10 can also include a middle-of-the-line (MOL) level and a frontside back-end-of-the-line (BEOL) structure located on the frontside of the semiconductor substrate (the MOL level and the frontside BEOL structure are also not shown in the drawings of the present application). The MOL level is located between the FEOL level and the frontside BEOL structure. The MOL level includes frontside contact structures (e.g., frontside gate contact structure and/or frontside source/drain contact structures) embedded in one or more ILD layers. The one or more ILD layers of the MOL level are composed of an ILD material including, for example, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0. All dielectric constants mentioned herein are measured in a vacuum unless otherwise stated. The frontside contact structures are composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. The frontside source/drain contact structure can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside BEOL structure is composed of an interconnect dielectric region having frontside metal wiring embedded therein; the frontside metal wiring present in the frontside BEOL structure is typically, but not necessarily always, signal wires. The interconnect dielectric region includes one or more interconnect dielectric material layers. The interconnect dielectric material layers can be composed of at least one of the ILD materials mentioned above. The frontside metal wiring can be in the form of metal lines, metal vias, a metal via/metal line combination or any combinations thereof. The frontside metal wiring is composed of an electrically conductive metal or an electrically conductive metal alloy. Exemplary electrically conductive metals include, but are not limited to, Cu, W, Al, Co, or Ru. An exemplary electrically conductive metal alloy is a Cu-Al alloy.

In some embodiments, a backside BEOL structure (also not specifically illustrated in the drawings of the present application) can be located on a backside of the semiconductor substrate that is present in semiconductor die 10. When present, the backside BEOL structure can be designed to delivery power from the backside of the device. The backside BEOL structure is composed of an interconnect dielectric region having backside metal wiring embedded therein. The interconnect dielectric region includes one or more interconnect dielectric material layers. The interconnect dielectric material layers can be composed of one of the ILD materials mentioned above. The backside metal wiring which can be in the form of metal lines, metal vias, a metal via/metal line combination or any combinations thereof is composed of an electrically conductive metal or an electrically conductive metal alloy, as both defined above. In addition to a backside BEOL structure, one or more backside ILD layers can be disposed between the backside BEOL structure and the semiconductor substrate. Backside contact structures can be present in the one of more backside ILD layers.

The semiconductor die 10 can be formed utilizing conventional techniques that are well known to those skilled in the art. As such, details regarding the formation of the semiconductor die 10 are not provided in this application.

Molding component 12 that can be employed in the present application is composed of any molding composite that is typically used in the semiconductor industry to encapsulate semiconductor devices. Notably, the molding component 12 is composed of a composite material that includes a molding resin such as, for example, an epoxy resin, and a filler such as, for example, silicon. The molding component can also include a hardener such as, for example, a phenolic hardener, a pigment, a release agent or any combination thereof. It is noted that the particle size of the filler that is present in the molding composite must be small enough to fill in the gaps that are located between the continuous stiffener element 12 and the semiconductor die 10. Typically, the size of the fillers present in the molding composite that provides the molding component 12 is ⅓ the gap size. For example, filler particle sizes between 1 microns and 3 microns can be typically used in the present application when the distance (i.e., gap) between the continuous stiffener element 12 and the semiconductor die 10 is from 10 microns to 20 microns. In some embodiments of the present application and to facilitate further warpage reduction of the electronic package, the filler of the molding component 12 can have a CTE that closely matches the CTE of both the stiffener material that provides the continuous stiffener element 14 and the carrier substrate 18. Stated in other terms, the molding component 12 can be formulated in such a manner to lowers its'CTE by selection of a filler type and by increasing the filler concentration. Notably, the filler type selected for the molding component 12 has a CTE that closely matches that of both the stiffener material that provides the continuous stiffener element 14 and the carrier substrate 18, and a high filler concentration of such CTE matching filler can lower the CTE of the molding component 12.

Continuous stiffener element 14 is a framing element (or wall) without any breaks or openings present therein. The continuous stiffener element 14 is located around the entire perimeter of the semiconductor die 10. The continuous stiffener element 14 that is employed in the present application is composed a stiffener material having a CTE that closely matches a CTE of the semiconductor substrate present in the semiconductor die 10. The stiffener material that is used typically has a Young's modulus that closely matches a Young's modulus of the carrier substrate 18. The closely matched Young's modulus between the stiffener material and the carrier substrate 18 can facilitate further warpage reduction of the electronic package.

The stiffener material that can be used in providing the continuous stiffener element 14 of the present application can include, but is not limited to, a semiconductor material as mentioned above, a carbide, a ceramic, a metal (including a metal alloy), SiN, AlN, diamond-like carbon or any combination or multilayered stack thereof. When a carbide is used in providing the continuous stiffener element 14, the carbide can include, but is not limited to, SiC or SiGeC or any combination thereof. When a ceramic is used in providing the continuous stiffener element 14, the ceramic includes a ceramic material typically has a hardness of about 7 Mohs scale or higher. The Mohs scale of hardness is a qualitative ordinal scale, from 1 to 10, characterizing scratch resistance of materials through the ability of harder materials to scratch softer materials. Illustrative examples of ceramics that can be used include, but are not limited to, Al₂O₃, Zr₂O₃, SiO₂, TiO₂, MgO, CaO, or any combination thereof. When a metal is used in providing the continuous stiffener element 14, the metal (or metal alloy) can include, but is not limited to, a nickel-iron alloy (such as, for example, INVAR 42®; a nickel-iron alloy containing about 41 nickel), an iron-nickel-cobalt alloy (such as, for example, COVAR® which has a CTE that closely matches Si) or any combination thereof. In one example, and when the carrier substrate 18 is composed of Si, Si can be used as the stiffener material that provides the continuous stiffener element 14. In such an embodiment, the molding component 12 can include a molding composite that includes silicon particles as the filler. This aspect of the present application facilities further warpage reduction of the electronic package.

In the present application, the continuous stiffener element 14 and the semiconductor die 10 are attached to carrier substrate 18. In some embodiments and as is illustrated in FIG. 1B, carrier substrate 18 can be an interposer structure which includes a semiconductor material core 22 sandwich between a first dielectric layer 20A and a second dielectric layer 20B. The semiconductor material core 22 is composed of one of the semiconductor materials mentioned above. In one embodiment, the semiconductor core 22 is composed of silicon. The first dielectric layer 20A and the second dielectric layer 20B can be composed of any dielectric material including an ILD material as mentioned above. The interposer structure illustrated FIG. 1B also includes electrically conductive wiring and at least one electrically conductive through via structure 24 (three of which are illustrated in FIG. 1B). The electrically conductive wiring can include first electrically conductive wires 28A present in the first dielectric layer 20A, and second electrically conductive wires 28B present in the second dielectric layer 20B. The first electrically conductive wires 28A and the second electrically conductive wires 28B are composed of an electrically conductive metal or electrically conductive metal alloy including those specified above. As is shown, one first electrically conductive wire 28A is in electrical contact with a first surface of one of the electrically conductive through via structures 24, and one second electrically conductive wire 28B is in electrically contact with a second surface (which is opposite the first surface) of the electrically conductive through via structure 24. Each electrically conductive through via structure 24 extends completely through the semiconductor material core 22 and partially into both the first dielectric layer 20A and the second dielectric layer 20B. Each electrically conductive through via structure 24 is composed of an electrically conductive metal or electrically conductive metal alloy as previously mentioned herein.

In addition to the electrically conductive wiring mentioned above, the interposer structure can also include metal bond pads 26 present in an uppermost portion of the first dielectric layer 28A. The metal bond pads 26 (which also provides wiring in the interposer structure) are composed of an electrically conductive metal or metal alloy. Although not illustrated in the drawings, the metal bond pads 26 can be electrically connected to the first electrically conductive wires 28A.

Other types of structures that can be used as carrier substate 18 include, but are not limited to, a semiconductor wafer (such as, for example, a Si wafer), a through silicon vias (TSV) structure, a SiC layer, a SiN layer, an Al₂O₃ layer of any combination or multilayered stack thereof.

In the embodiment illustrated in FIG. 1B, the continuous stiffener element 14 and the semiconductor die 10 are attached to the carrier substrate 18 using at least one first bonding element 16. Each first bonding element 16 is embedded in a portion of the molding component 12 that is located beneath the semiconductor die 10. In the illustrated embodiment, each first bonding element 16 is typically in electrical contact with one of the metal bond pads 26. Also illustrated in FIG. 1B, are second bonding elements 30 (although a plurality of second bonding elements 30 are described and illustrated, it is possible to use a single second bonding element). Each second bonding element 30 is located beneath the second dielectric layer 20B of the interposer structure and is in electrical contact with one of the second electrically conductive wires 28B. The first bonding elements 16 and the second bonding elements 30 are composed a solder ball material including lead-containing solder or lead-free solder, a solder bump, a microbump, a ball grid array (BGA) ball, a controlled collapse chip connection (C4) bump, a thermoplastic adhesive, a thermoset adhesive or any other like material that is used in the semiconductor industry for attaching one structure to another structure. The first bonding elements 16 can be compositionally the same as, or compositionally different from, the second bonding elements 30. A thermoplastic adhesive is an adhesive that melts or softens on heating and rehardens on cooling without undergoing substantial chemical change. Illustrative examples of thermoplastic adhesives that can be employed include, but are not limited to, a polyvinyl chloride, a polyvinyl acetate, or an acrylic. A thermoset adhesive is an adhesive that relies on a reaction(e.g., cross-linking) that transforms liquid or gel formulations into a solid, reliable adhesive. Illustrative examples of thermoplastic adhesives that can be employed include, but are not limited to, an epoxy resin, a polyester or a phenolic formaldehyde resin.

Referring now to FIG. 1C, there is illustrated an electronic package of the present application without molding component 12 and on carrier substrate 18 and after dicing. Notably, FIG. 1C illustrates an electronic package structure in accordance with an embodiment of the present application which includes a continuous stiffener element 14 located around an entire perimeter of a semiconductor die 10. The molding component which would be located between the continuous stiffener element 14 and the semiconductor die 10 is not illustrated in FIG. 1C for clarity.

Notably, FIGS. 1A-1B and FIG. 1C (when the molding component 12 is present) represent an electronic package in accordance with the present application. Notably, the electronic packing structure includes continuous stiffener element 14 located around an entire perimeter of semiconductor die 10, molding component 12 located between, and beneath, the continuous stiffener element 14 and the semiconductor die 10, and carrier substrate 18 attached to the continuous stiffener element 14 and the semiconductor die 10. In accordance with the present application and to reduce warpage in the electronic package, the continuous stiffener element 14 is composed of a stiffener material having a CTE that closely matches a CTE of the carrier substrate 18.

In embodiments of the present application, the carrier substrate 18 (see, for example, FIG. 1B) is spaced apart from the semiconductor die 10 and the continuous stiffener element 14 by the molding component 12. The aspect of the present application allows for an area in which mounting of the semiconductor die 10 and the continuous stiffener element 14 to the carrier substrates 18 occurs.

In embodiments, the stiffener material of the continuous stiffener element 14 illustrated in FIGS. 1A-1C includes a semiconductor material, a carbide, a ceramic, a metal, SiN, AlN, diamond-like carbon or any combination or multilayered stack thereof.

In some embodiments, the stiffener material of the continuous stiffener element 14 illustrated in FIGS. 1A-1C has a Young's modulus that closely matches a Young's modulus of the carrier substrate 18. The aspect of the present application can facilitate further warpage reduction in the electronic package.

In some embodiments, the molding component 12 illustrated in FIGS. 1A-1B includes a filler, and the filler has a CTE that closely matches the CTE of both the stiffener material of the continuous stiffener element 14 and the carrier substrate 18. The aspect of the present application can facilitate further warpage reduction in the electronic package.

In some embodiments, the stiffener material of the continuous stiffener element 14 and the carrier substrate 18 both include silicon. This aspect of the present application also for a substantially matched CTE.

In embodiments, the carrier substrate 18 illustrated in FIG. 1B is attached to the continuous stiffener element 14 and the semiconductor die 10 by at least one first bonding element.16.

In some embodiments, the carrier substrate 18 as illustrated in FIG. 1B includes an interposer structure, and the interposer structure includes electrically conductive wiring and at least one electrically conductive through via structure.

In embodiments of the present application, the molding component 12 is composed of a composite material that comprises a molding resin and a filler.

Although FIGS. 1A-1C, illustrates a single semiconductor die 10, the electronic package of the present application (such as the one illustrated in FIGS. 1A-1C) can include a plurality of semiconductor die 10. When a plurality of semiconductor die 10 is employed, the electronic package includes a plurality of semiconductor die 10 attached to carrier substrate 18. Each semiconductor die 10 of the plurality of semiconductor die is surrounded by continuous stiffener element 14, in which the continuous stiffener element 14 is composed of a stiffener material having a coefficient of CTE that closely matches a CTE of the carrier substrate 18. The electronic package also includes molding component 12 located between, and beneath, the continuous stiffener element 14 and each semiconductor die 10. The closely matching CTEs provide a reduced warpage to an electronic package that includes a plurality of semiconductor die 10. Embodiments as discussed above in paragraphs 0041-0048 apply for the case in which a plurality of semiconductor die 10 are present.

Referring now to FIG. 2, there is illustrated an exemplary electronic structure in accordance with an embodiment of the present application. The exemplary electronic structure illustrated in FIG. 2 includes a 0^{th} level package (i.e., the electronic package of the present application as illustrated, for example, in FIG. 1B) attached to first laminate 44 (providing a 1^{st} level package) and then to a second laminate 52 (providing a 2^{nd} level package); the second laminate 52 is typically a circuit board). The 0^{th} level package illustrated in FIG. 2 includes elements mentioned above with respect to the electronic package illustrated in FIGS. 1A-1C. Notably, the 0^{th} level package includes continuous stiffener element 14 located around an entire perimeter of a semiconductor die 10, molding component 12 located between, and beneath, the continuous stiffener element 14 and the semiconductor die 10, and carrier substrate 18 attached to the continuous stiffener element 14 and the semiconductor die 10. In the 0^{th} level package, the continuous stiffener element 14 is composed of a stiffener material having a CTE that closely matches a CTE of the carrier substrate 18. In some embodiments and as is illustrated in FIG. 2, carrier substrate 18 can be an interposer structure as defined above. Although an interposer structure is illustrated in FIG. 2 as the carrier substrate 18, other types of carrier substrates as mentioned above besides an interposer structure can be used. In the illustrated embodiment, second bonding elements 30 are used to attach the carrier substrate 18 to first laminate 44. In some embodiments (and as illustrated in FIG. 2), the second bonding elements 30 can be embedded in an underfill material 32. In some embodiments, underfill material 32 can be omitted. When present, underfill material 32 fills the spacing between the carrier substrate 18 and the first laminate 44. In some embodiments, the underfill material 32 is an electrically insulated adhesive for protecting the second bonding elements 30 and/or securing the package structure of the present application. In some embodiments, the underfill material 32 is composed of an epoxy, resin, an epoxy molding compound, another suitable underfill material, and/or a combination thereof.

The exemplary electronic structure illustrated in FIG. 2 further includes a first (1^{st}) level stiffener element 40 located around a perimeter of the continuous stiffener element 14 (i.e., 0^{th} level stiffener element). The 1^{st} level stiffener element 40 can include one of the stiffener materials mentioned above. The stiffener material that provides the 1st stiffener element 40 can, but not necessarily always, have a CTE that closely matches the CTE of the first laminate 44. It is preferred that the CTE of the 1^{st} level stiffener element 40 closely matches the CTE of the first laminate 44 to further prevent warpage of the structure illustrated in FIG. 2. The first level stiffener element 40 can be continuous or it can be a discontinuous element. A first level stiffener element 40 that is continuous is preferred since the continuous aspect would further reduce warpage in such a structure. In some embodiments, the stiffener material that provides the 1st stiffener element 40 has a Young's modulus that closely matches a Young's modulus of the first laminate 44. This aspect of the present application facilitates further warpage reduction of the electronic packaging structure.

The electronic structure further includes 1^{st} level molding component 42 that is located between the zero-level package and the 1^{st} level stiffener element 40. The 1^{st} level molding component 42 is located in the gap between the 1^{st} level stiffener element 40 and the 0^{th} level package, and the 1^{st} level molding component 42 is located beneath the 1^{st} level stiffener element 40. The 1^{st} level molding component 42 is composed of any molding component including those mentioned above for molding component 14. In some embodiments, the 1^{st} level molding component 42 includes a filler that has a CTE that closely matches the CTE of the 1^{st} level stiffener element 40 and/or the first laminate 44. By closely matching the CTE of filler of the 1^{st} level molding component 42 with the CTE of the 1^{st} level stiffener element 40 and/or the first laminate 44 further warpage reduction can be provided.

The first laminate 44 (and second laminate 52) includes any laminate material such as, for example, Si, which is well known to those skilled in the art. In some embodiments, upper metal bond pads 46A are located on a first side of the laminate 44 and lower metal bond pads 46B are located on a second side of the first laminate 44 which is opposite the first side of the first laminate 44. The upper and lower metal bond pads are composed of an electrically conductive material as defined above. In embodiments, at least one through via structure 48 is present in the first laminate 44. The at least one through via structure 46 is composed of an electronically conductive material as defined above.

The first laminate 44 is attached to a second laminate 52 (typically a circuit board) by means of third bonding elements 50. The third bonding elements 50 are composed of any of the materials mentioned above for the first bonding elements 16 and second bonding elements 30.

Notably, FIG. 2 illustrates an electronic packaging structure that includes a 0^{th} level package including continuous stiffener element 14 located around an entire perimeter of semiconductor die 10, molding component 12 located between and beneath the continuous stiffener element 14 and the semiconductor die 10, and carrier substrate 18 attached to the continuous stiffener element 14 and the semiconductor die 10, in which the continuous stiffener element 14 is composed of a stiffener material having a CTE that closely matches a CTE of the carrier substrate 18. The closely matched CTEs facilitates warpage reduction in the 0^{th} level package. The electronic packaging structure illustrated in FIG. 2 further includes first level stiffener element 40 located adjacent to the 0^{th} level package, a first level molding component 42 located between the 0^{th} level package and the first level stiffener element 14, and beneath the first level stiffener element 10, and a first laminate 44 attached to the carrier substrate 18 and in contact with the first level molding component 42.

In some embodiments, the electronic packaging structure can further include second laminate 52 attached to the first laminate 44.

In some embodiments, the stiffener material of the continuous stiffener element 14 has a Young's modulus that closely matches a Young's modulus of the carrier substrate 18. The aspect of the present application can facilitate further warpage reduction of the 0^{th} level package.

In some embodiments, the molding component 12 includes a filler, and the filler has a CTE that closely matches the CTE of both the stiffener material of the continuous stiffener element 14 and the carrier substrate 18. The aspect of the present application can facilitate further warpage reduction of the 0^{th} level package

In some embodiments, the stiffener material of the continuous stiffener element 14 and the carrier substrate 18 both comprise silicon. This aspect of the present application provides substantially matched CTEs of the continuous stiffener element 14 and the carrier substrate 18 of the 0^{th} level package

In some embodiments, the molding component 12 of the 0^{th} level package is composed of a composite material that comprises a molding resin and a filler.

In some embodiments, the first level stiffener element 40 is composed of a stiffener material having a CTE that closely matches a CTE of the first laminate 44. This aspect of the present application provides warpage reduction of the 1^{st} level package.

In some embodiments, the first level stiffener element 40 is composed of a stiffener material having a Young's modulus that closely matches a Young's modulus of the first laminate 44. This aspect of the present application provides warpage reduction of the 1^{st} level package.

In some embodiments, the first level stiffener element 40 is a continuous stiffener element. This aspect of the present application provides warpage reduction of the 1^{st} level package.

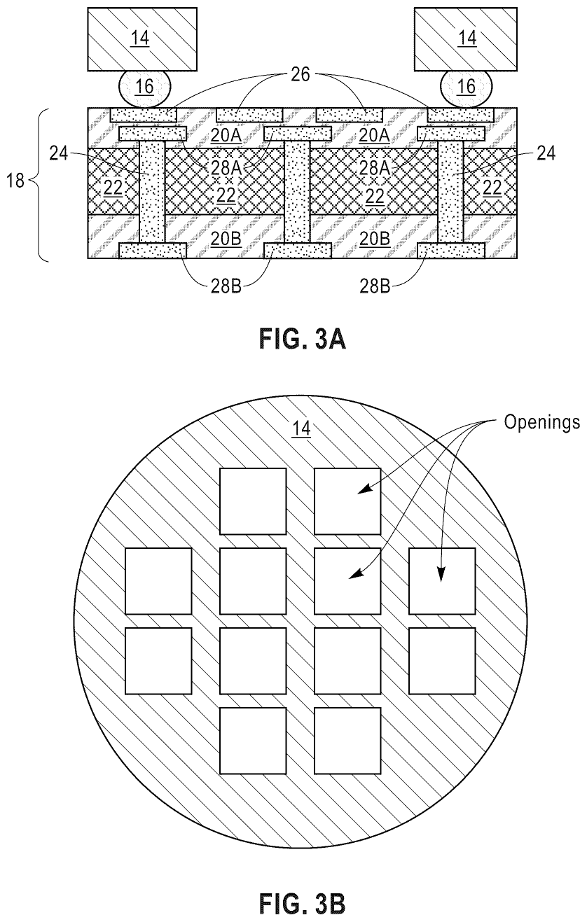

Reference will now be made to FIGS. 3A-5A and FIGS. 3B-5B which illustrate an electronic package structure of the present application through various processing steps. Notably, FIGS. 3A-5A illustrate various processing steps of forming an electronic package of the present application in die form, while FIGS. 3B-5B illustrate various processing steps of forming an electronic package of the present application in wafer form.

Referring first to FIG. 3A, there is illustrated an initial 0^{th} level electronic package in die form in accordance with an embodiment of the present application. The initial 0^{th} level electronic package includes a continuous stiffener element 14 attached to (i.e., mounted on) carrier substrate 18 by means of using first bonding elements 16. In the illustrated embodiment, the carrier substrate 18 is an interposer structure as defined above; although other types of carrier substrates as mentioned above can be used in place of the interposer structure illustrated in FIG. 3A. In some embodiments, the first bonding elements 16 are formed in electrical contact with one of the metal bond pads 26 of the carrier substrate 18. In some embodiments, the first bonding elements 16 can be formed on a surface of the metal bond pads 26, then the continuous stiffener element 14 is brought into contact with the first bonding elements 16, and thereafter an optional solder reflow can be performed to form solder joints. In other embodiments, the first bonding elements 16 can be applied to the continuous stiffener element 14 in locations that correspond to the metal bond pads 26, then the continuous stiffener element 14 containing the first bonding elements 16 is brought into contact with the metal bond pads 26, and thereafter an optional solder reflow can be performed to form solder joints. FIG. 3B shows an initial 0^{th} level electronic package similar to that shown in FIG. 3A, but in wafer form rather than chip form.

The continuous stiffener element 14 has openings formed therein (see, for example, FIGS. 3A and 3B). Each opening corresponds to an area in which a semiconductor die 10 will be subsequently placed into. The continuous stiffener element 14 can be formed using water cutting, laser etching, photolithography and reactive ion etching (RIE) or any other like process that is capable of forming a continuous stiffer element 14. The shape of the continuous stiffener element 10 typically matches that of the semiconductor die 10 (or processed wafer).

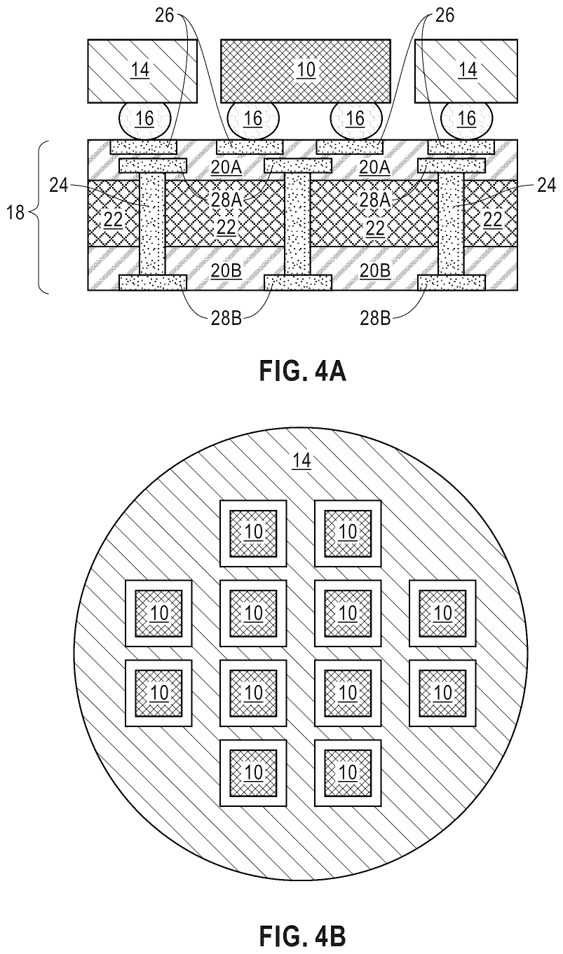

Referring now to FIG. 4A, there is illustrated the initial 0^{th} level electronic package of FIG. 3A after attaching a semiconductor die 10 thereto. In the illustrated embodiment, the semiconductor die 10 is placed into one of the openings present in the continuous stiffener element 14 such that the semiconductor die 10 does not contact any surface of the continuous stiffener element 14. Instead, a gap exists between the semiconductor die 10 and an edge of the continuous stiffener element 14. This gap extends around the entire perimeter of the semiconductor die 10. In some embodiment, the semiconductor die 10 can be replaced with a processed wafer which can be diced in a subsequent process step of the present application.

In the illustrated embodiment, the attaching of the semiconductor die 10 to the carrier substrate 18 is performed utilizing a first bonding element 16. In such an embodiment, the first bonding element 16 is formed in electrical contact with one of the metal bond pads 26. In some embodiments, the first bonding element 16 can be formed on a surface of one of the metal bond pads 26, then semiconductor die 10 is brought into contact with the first bonding element 16, and thereafter an optional solder reflow can be performed to form solder joints. In other embodiments, the first bonding element 16 can be applied to the semiconductor die 10 in a locations that correspond to the one metal bond pad 26, then the semiconductor die 10 containing the first bonding element 16 is brought into contact with the metal bond pad 26, and thereafter an optional solder reflow can be performed to form solder joints. Note that after attaching the semiconductor die 10 to substrate 18, a gap exists between the continuous stiffener element 14 and the semiconductor die. FIG. 4B shows an initial 0^{th} level electronic package similar to that shown in FIG. 4A, but in wafer form rather than chip form.

It is noted that although the present application describes and illustrates the attachment of the continuous stiffener element 14 prior to the attachment of the semiconductor die 10, the present application works when the semiconductor die 10 is attached prior to the continuous stiffener element 14.

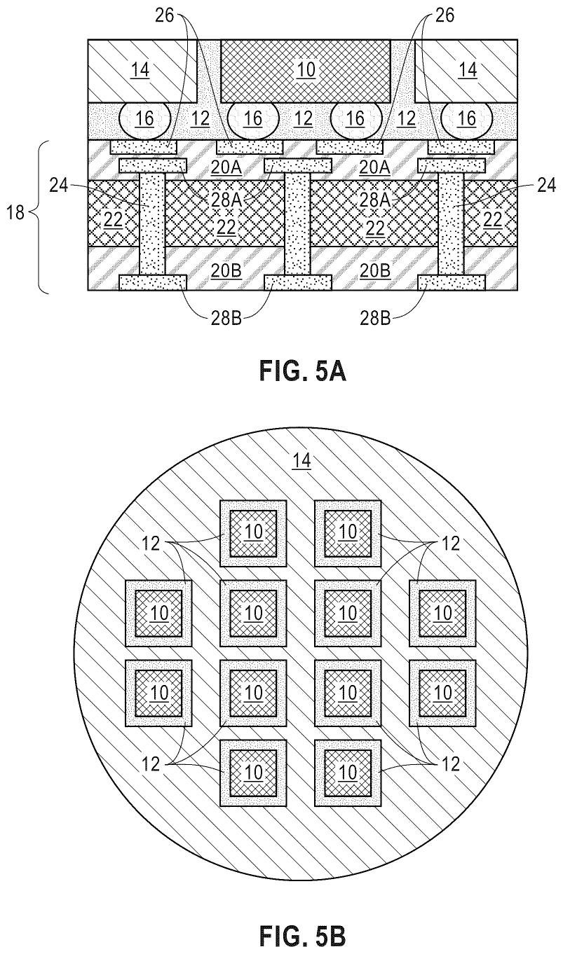

Referring now to FIG. 5A, there is illustrated the initial 0^{th} level electronic package of FIG. 4A after forming molding component 12 in gaps that are located between the continuous stiffener element 14 and semiconductor die 10. It is noted that the molding component 12 is also formed beneath the continuous stiffener element 14 and the semiconductor die 10. The forming the molding component 12 in the gaps includes application of the molding composition into the gaps, followed by a curing process. After curing, a planarization process such as, for example, chemical mechanical planarization (CMP) can be performed to remove any molding component 12 that is formed on top of both the continuous stiffener element 14 and the semiconductor die 10. FIG. 5B shows an initial 0^{th} level electronic package similar to that shown in FIG. 4A, but in wafer form rather than chip form.

In some embodiments, a dicing process can be performed between two semiconductor die 10 that are attached to the carrier substrate 18. The dicing process occurs in a portion of the continuous stiffener element 14 and provides individual electronic package structures in accordance with the present application attached to a diced portion of carrier substrate 18.

The processing flow illustrated in FIGS. 3A-5A provides an electronic package structure (such as, illustrated in FIGS. 1A and 1B) that includes continuous stiffener element 14 located around an entire perimeter of semiconductor die 10, molding component 12 located between the continuous stiffener element 14 and the semiconductor die 10, and carrier substrate 18 attached to the continuous stiffener element 14 and the semiconductor die 10. To reduce warpage, the continuous stiffener element 14 is composed of a stiffener material having a CTE that closely matches a CTE of the carrier substrate 18. A similar electronic package but in wafer form (see, for example, FIG. 1C) is provided by using the processing steps illustrated in FIGS. 3B-5B. The continuous aspect of the continuous stiffener element 14 together with having the CTE of the continuous stiffener element 14 closely match the CTE of the carrier wafer 18 reduces warpage of the resultant 0^{th} level package.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. An electronic package comprising:
a continuous stiffener element located around an entire perimeter of a semiconductor die;
a molding component located between, and beneath, the continuous stiffener element and the semiconductor die; and
a carrier substrate attached to the continuous stiffener element and the semiconductor die, wherein the continuous stiffener element is composed of a stiffener material having a coefficient of thermal expansion (CTE) that closely matches a CTE of the carrier substrate.

2. The electronic package of claim 1, wherein the carrier substrate is spaced apart from the semiconductor die and the continuous stiffener element by the molding component.

3. The electronic package of claim 1, wherein the stiffener material comprises a semiconductor material, a carbide, a ceramic, a metal, SiN, AlN, diamond-like carbon or any combination or multilayered stack thereof.

4. The electronic package of claim 1, wherein the stiffener material has a Young's modulus that closely matches a Young's modulus of the carrier substrate.

5. The electronic package of claim 1, wherein the molding component comprises a filler, and the filler has a CTE that closely matches the CTE of both the stiffener material and the carrier substrate.

6. The electronic package of claim 1, wherein the stiffener material and the carrier substrate both include silicon.

7. The electronic package of claim 1, wherein the carrier substrate is attached to the continuous stiffener element and the semiconductor die by at least one first bonding element.

8. The electronic package of claim 1, wherein the carrier substrate comprises an interposer structure, and the interposer structure comprises electrically conductive wiring and at least one electrically conductive through via structure.

9. The electronic package of claim 1, wherein the molding component is composed of a composite material that comprises a molding resin and a filler.

10. An electronic package comprising:
a plurality of semiconductor die attached to a carrier substrate, wherein each semiconductor die of the plurality of semiconductor die is surrounded by a continuous stiffener element, in which the continuous stiffener element is composed of a stiffener material having a coefficient of CTE that closely matches a CTE of the carrier substrate, and a molding component located between, and beneath, the continuous stiffener element and each semiconductor die.

11. An electronic packaging structure comprising:
a 0^{th} level package comprising a continuous stiffener element located around an entire perimeter of a semiconductor die, a molding component located between and beneath the continuous stiffener element and the semiconductor die, and a carrier substrate attached to the continuous stiffener element and the semiconductor die, wherein the continuous stiffener element is composed of a stiffener material having a coefficient of thermal expansion (CTE) that closely matches a CTE of the carrier substrate;
a first level stiffener element located adjacent to the 0^{th} level package;
a first level molding component located between the 0^{th} level package and the first level stiffener element, and beneath the first level stiffener element; and
a first laminate attached to the carrier substrate and in contact with the first level molding component.

12. The electronic packaging structure of claim 11, further comprises a second laminate attached to the first laminate.

13. The electronic packaging structure of claim 11, wherein the stiffener material of the continuous stiffener element has a Young's modulus that closely matches a Young's modulus of the carrier substrate.

14. The electronic packaging structure of claim 11, wherein the molding component comprises a filler, and the filler has a CTE that closely matches the CTE of both the stiffener material of the continuous stiffener element and the carrier substrate.

15. The electronic packaging structure of claim 11, wherein the stiffener material of the continuous stiffener element and the carrier substrate both comprise silicon.

16. The electronic packaging structure of claim 11, wherein the molding component is composed of a composite material that comprises a molding resin and a filler.

17. The electronic package structure of claim 11, wherein the first level stiffener element is composed of a stiffener material having a CTE that closely matches a CTE of the first laminate.

18. The electronic packaging structure of claim 11, wherein the first level stiffener element is composed of a stiffener material having a Young's modulus that closely matches a Young's modulus the first laminate.

19. The electronic packaging structure of claim 11, wherein the first level stiffener element is a continuous stiffener element.
